(19) United States
(12) Patent Application Publication
(10) Pub. No.: US 2010/0032747 A1
(43) Pub. Date: Feb. 11, 2010

(54) SEMICONDUCTOR MEMORY DEVICE AND METHOD FOR MANUFACTURING THE SAME

(76) Inventors: Takayuki OKAMURA, Machida-shi (JP); Keiko Ariyoshi, Delmar, NY (US)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/506,534

(22) Filed: Jul. 21, 2009

(30) Foreign Application Priority Data
Aug. 8, 2008 (JP) 2008-205531

(51) Int. Cl. H01L 29/792; H01L 21/28

(52) U.S. Cl. 257/326; 438/591; 257/E29.309; 257/E21.21; 257/E21.679; 257/E27.081

(57) ABSTRACT

A semiconductor memory device includes a plurality of memory cell transistors each having a gate electrode section including a charge accumulation layer formed on a semiconductor substrate via a gate insulating film, a first insulating film formed using a material with a higher dielectric constant than the gate insulating film, a control gate, an impurity diffusion layer functioning as a source or a drain, and a plurality of barrier films formed on a side surface of the gate electrode section so as to cover a side surface of at least the first insulating film and formed between the first insulating film and the control gate. The device further includes a plurality of second insulating films formed on the semiconductor substrate and each formed between the gate electrode sections of adjacent ones of the plurality of memory cell transistors.

### CROSS-REFERENCE TO RELATED APPLICATIONS

This application is based upon and claims the benefit of priority from prior Japanese Patent Application No. 2008-205531, filed Aug. 8, 2008, the entire contents of which are incorporated herein by reference.

### BACKGROUND OF THE INVENTION

1. Field of the Invention

The present invention relates to a semiconductor memory device and a method for manufacturing the semiconductor memory device. More specifically, the present invention relates to the structure of a gate electrode of a memory cell in a NAND flash memory.

2. Description of the Related Art

Memory cells in NAND flash memories conventionally adopt a metal oxide nitride oxide semiconductor (MONOS) structure including a stacked gate with a charge accumulation layer, a block layer, and a control gate. In the MONOS structure, a material exhibiting physical properties such as a high dielectric constant and a large barrier height is adopted for an insulating layer as the block layer (see, for example, Jpn. Pat. Appln. KOKAI Publication No. 2006-229233). Two reasons for the adoption of such a material in connection with the required functions of the block layer are described below.

First, the block layer needs to have a large physical film thickness in order to function as a barrier to prevent charges accumulated in an insulating layer from escaping from the insulating film.

Second, the block layer needs to have a high dielectric constant in order to apply a voltage to a control gate of a gate electrode to be sufficiently transmitted to a gate insulating film.

Thus, based on these two requirements, a possible material for the block layer is, for example, Al₂O₃.

However, in connection with data holding characteristics and the like, a material with a higher dielectric constant is conventionally preferably used as a material for the block layer.

### BRIEF SUMMARY OF THE INVENTION

According to a first aspect of the present invention, there is provided a semiconductor memory device comprising a plurality of memory cell transistors each comprising a gate electrode section including a charge accumulation layer formed on a semiconductor substrate via a gate insulating film and in which charges are accumulated, a first insulating film formed on the charge accumulation layer using a material with a higher dielectric constant than the gate insulating film, and a control gate formed on the first insulating film, and an impurity diffusion layer functioning as a source or a drain; a plurality of barrier films formed on a side surface of the gate electrode section so as to cover a side surface of at least the first insulating film and formed between the first insulating film and the control gate; and a plurality of second insulating films formed on the semiconductor substrate and each formed between the gate electrode sections of adjacent ones of the plurality of memory cell transistors; wherein during annealing of the plurality of memory cell transistors, the plurality of barrier films prevent atoms comprising the second insulating film and the control gate from diffusing to the first insulating film.

According to a second aspect of the present invention, there is provided a semiconductor memory device comprising a plurality of memory cell transistors each comprising a gate electrode section including a charge accumulation layer formed on a semiconductor substrate via a gate insulating film, a first insulating film formed on the charge accumulation layer using a material with a higher dielectric constant than the gate insulating film, and a control gate formed on the first insulating film, and an impurity diffusion layer as a source or a drain; a first barrier film formed on a side surface of each gate electrode section to cover a side surface of at least the first insulating film; a second barrier film formed between the first insulating film and the control gate; and a plurality of second insulating films formed on the semiconductor substrate and each formed between the gate electrode sections of adjacent ones of the plurality of memory cell transistors; wherein the first and second barrier films prevent diffusion of an electric field traveling from the control gate to the gate insulating film.

According to a third aspect of the present invention, there is provided a semiconductor memory device manufacturing method comprising forming a charge accumulation layer on a semiconductor substrate via a gate insulating film; forming a first insulating film on the charge accumulation layer and a dielectric of the first insulating film is higher than of the gate insulating film; forming a barrier film on the first insulating film; forming a conductive film on the barrier film; patterning the conductive film, the barrier film, and the first insulating film to form a gate electrode section; injecting an impurity into a surface of the semiconductor substrate to form a source and a drain, thus forming a memory cell transistor; forming a second insulating film on a side surface of the first insulating film in the gate electrode section; forming a third insulating film covering the memory cell transistor, on the semiconductor substrate; and annealing the memory cell transistor after forming the second insulating film.

### BRIEF DESCRIPTION OF THE SEVERAL VIEWS OF THE DRAWING

FIG. 1 is a block diagram showing an example of the configuration of a semiconductor memory device (NAND flash memory) according to a first embodiment of the present invention;

FIG. 2 is a plan view showing an example of the configuration of a memory cell array in the NAND flash memory;

FIG. 3 is a sectional view taken along line III-III in FIG. 2;

FIG. 4 is a sectional view illustrating a first manufacturing step for the NAND flash memory;

FIG. 5 is a sectional view illustrating a second manufacturing step for the NAND flash memory;

FIG. 6 is a sectional view illustrating a third manufacturing step for the NAND flash memory;

FIG. 7 is a sectional view illustrating a fourth manufacturing step for the NAND flash memory;

FIG. 8 is a sectional view illustrating a fifth manufacturing step for the NAND flash memory;

FIG. 9 is a sectional view illustrating a sixth manufacturing step for the NAND flash memory;

FIG. 10 is a diagram showing the configuration of a sputtering apparatus used to deposit a block layer;

FIG. 11 is a sectional view showing an example of the configuration of a semiconductor memory device (NAND flash memory) according to a second embodiment of the present invention;

FIG. 12 is a sectional view illustrating a manufacturing step for the NAND flash memory according to a second embodiment of the present invention;

FIG. 13 is a sectional view illustrating a manufacturing step following to FIG. 12;

FIG. 14 is a sectional view illustrating a manufacturing step following to FIG. 13;

FIG. 15 is a sectional view showing an example of the configuration of a semiconductor memory device (NAND flash memory) according to a modification of the first embodiment of the present invention; and

FIG. 16 is a sectional view showing an example of the configuration of a semiconductor memory device (NAND flash memory) according to a modification of the second embodiment of the present invention.

### DETAILED DESCRIPTION OF THE INVENTION

Embodiments of the present invention will be described with reference to the accompanying drawings. It should be noted that the drawings are schematic ones and so are not to scale. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### First Embodiment

A semiconductor memory device and a method for manufacturing the semiconductor memory device according to a first embodiment of the present invention will be described below. The present embodiment will be described by taking a NAND flash memory including memory cells with a MONOS structure as an example.

### <General Configuration of the NAND Flash Memory>

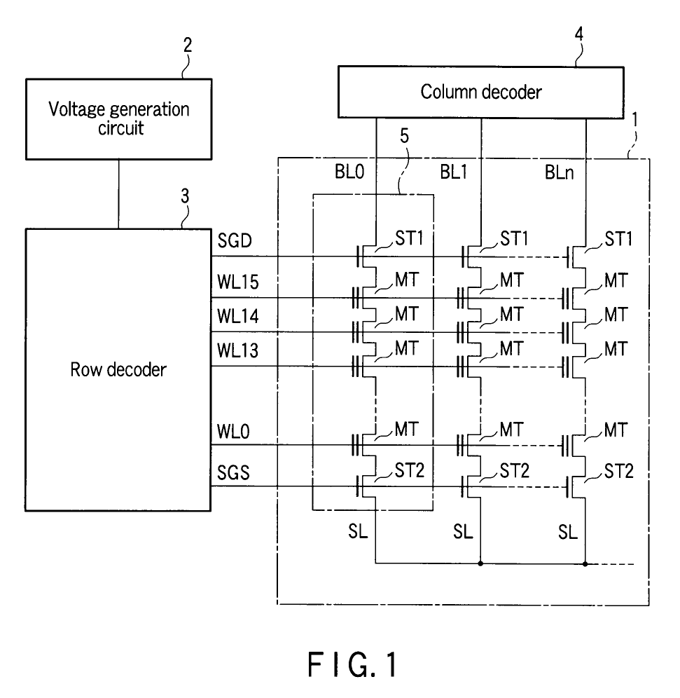

First, the general configuration of the NAND flash memory will be described with reference to FIG. 1. FIG. 1 is a block diagram of the NAND flash memory according to the present embodiment.

As shown in FIG. 1, the NAND flash memory includes a memory cell array 1, a voltage generating circuit 2, a row decoder 3, and a column decoder 4.

The memory cell array 1 includes a plurality of nonvolatile memory cell transistors MT capable of holding data. Each of the memory cell transistors MT is, for example, an n-channel metal oxide semiconductor (MOS) transistor including a stacked gate with a charge accumulation layer and a control gate electrode. A control gate electrode of the memory cell transistor MT functions as a word line WL. A drain (D) region of the memory cell transistor MT is connected indirectly to a bit line BL. A source (S) region of the memory cell transistor MT is connected indirectly to a source line SL.

The voltage generation circuit 2 generates a voltage and supplies the generated voltage to the row decoder 3.

The column decoder 4 selects a column direction for the memory cell array 1 based on a column address provided by a control section (not shown in the drawings). That is, the column decoder 4 selects the bit line BL corresponding to the column address.

During a data write operation, a data read operation, and a data erase operation, the row decoder 3 selects a row direction for the memory cell array 1 based on a row address provided by the control section (not shown in the drawings). That is, the row decoder 3 applies voltages to select gate lines SGD and SGS and word lines WL0 to WL15 according to the row address.

### <Configuration of the Memory Cell Array 1>

Now, the configuration of the memory cell array 1 will be described in detail with reference to FIG. 1.

The memory cell array 1 includes a plurality of NAND cells 5 in each of which the nonvolatile memory cell transistors MT capable of holding data are connected in series. Each of the NAND cells 5 includes, for example, 16 memory cell transistors MT and select transistors ST1 and ST2. Each of the memory cell transistors MT is, for example, an n-channel MOS transistor with a MONOS stacked gate. The MONOS stacked gate has the following configuration. That is, the stacked gate has a charge accumulation layer (insulating film) formed on a p-type semiconductor substrate via a gate insulating film, an insulating film (hereinafter referred to as a block layer) formed on the charge accumulation layer and having a higher dielectric constant than the charge accumulation layer, an insulating film formed on the block layer, and a control gate electrode formed on the insulating film. The number of memory cell transistors MT is not limited to 16 but may be 8, 32, 64, 128, 256, or the like; no limitation is imposed on the number of memory cell transistors MT. The adjacent memory cell transistors MT share a source region or a drain region. The memory cell transistors MT are arranged between select transistors ST1 and ST2 so that current paths in the memory cell transistors MT are connected in series. The drain region of one of the series-connected memory cell transistors MT which is located at one end of the array of memory cell transistors MT is connected to the source region of select transistor ST1. The source region of one of the series-connected memory cell transistors MT which is located at the other end of the array is connected to the drain region of select transistor ST2.

The control gate electrodes of the memory cell transistors MT on the same row are connected to one of word lines WL0 to WL15. The gate electrodes of select transistors ST1 in the NAND cells 5 on the same row are all connected to select gate line SGD. The gate electrodes of select transistors ST2 in the NAND cells 5 on the same row are all connected to select gate line SGS. For simplification of description, when not distinguished from one another below, the word lines WL0 to WL15 may be simply referred to as the word lines WL. Furthermore, in the memory cell array 1, the drain regions of select transistors ST1 on the same column are all connected to one of bit lines BL0 to BLn (n is a natural number). Similarly, when not distinguished from one another, the bit lines BL0 to BLn may be collectively referred to as the bit lines BL. The source regions of select transistors ST2 in the NAND cells 5 are all connected to the source line SL. Not both select transistors ST1 and ST2 are required. One of the select transistors may be omitted provided that the remaining select transistor allows the corresponding NAND cell 5 to be selected.

FIG. 1 shows only one row of the NAND cell 5. However, plural rows of NAND cells 5 may be provided in the memory cell array 1. In this case, the NAND cells 5 on the same column are connected to the same bit line BL. Furthermore, data is written, at a time, to the memory cell transistors MT on the same row connected to the same word line WL. This unit is called a page. Moreover, data is erased from the plurality of NAND cells 5 on the same row at a time. This unit is called a memory block.

### <Details of the Memory Cell Array 1>

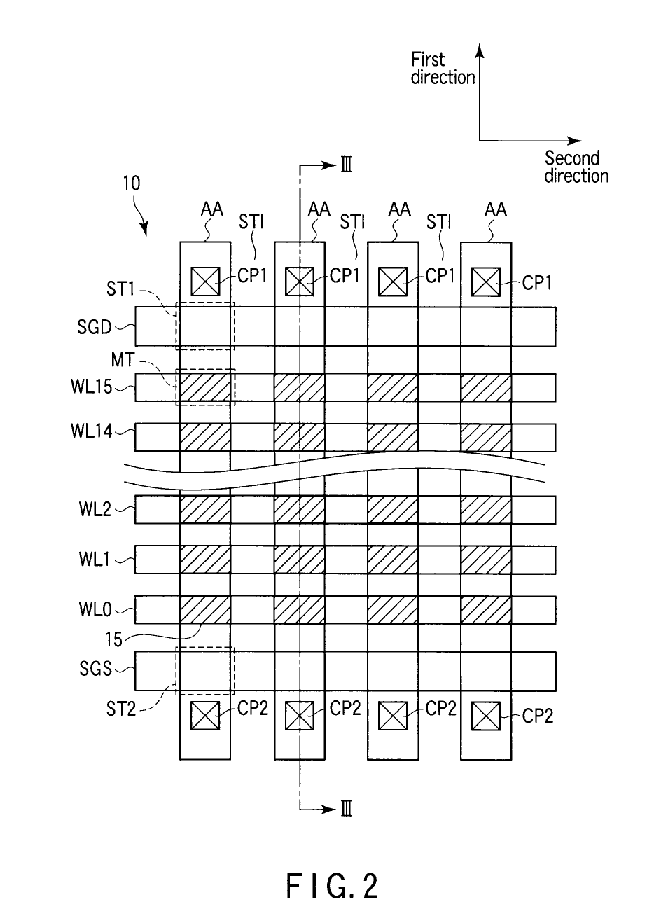

Now, the planar configuration of the memory cell array 1 configured as described above will be described. FIG. 2 is a plan view of the memory cell array 1.

As shown in FIG. 2, element regions AA arranged in striped form along a first direction are provided in a p-type semiconductor substrate 10 along a second direction orthogonal to the first direction. An isolation region ST1 is formed between the adjacent element regions AA to electrically separate the element regions AA from each other. A plurality of the word lines WL and select gate lines SGD and SGS arranged in a striped form are formed along the second direction so as to span a plurality of the element regions AA. A charge accumulation layer 15 is provided in each of the regions where the word line WL and the element region AA cross each other. The memory cell transistor MT is provided in each of the regions where the word line WL and the element region AA cross each other. Select transistor ST1 is provided in each of the regions where select gate line SGD and the element region AA cross each other. Select transistor ST2 is provided in each of the regions where select gate line SGS and the element region AA cross each other. An impurity diffusion layer corresponding to the source or drain region of the memory cell transistor MT and select transistors ST1 and ST2 is formed in the element region AA between the word lines WL located adjacent to each other in the first direction, in the element region AA between select gate lines SGD located adjacent to each other in the first direction, in the element region AA between select gate lines SGS located adjacent to each other in the first direction, and in the element region AA between the word line WL and each of select gate lines SGD and SGS located adjacent to each other in the first direction.

The impurity diffusion layer formed in the element region AA between select gate lines SGD, SGD functions as the drain region of select transistor ST1. A contact plug CP1 is formed on each drain region. Contact plug CP1 is connected to a corresponding one of the bit lines BL, provided in a striped form along the first direction. Furthermore, the impurity diffusion layer formed in the element region AA between select gate lines SGS, SGS functions as the source region of select transistor ST2. A contact plug CP2 is formed on each source region. Contact plug CP2 is connected to the source line SL.

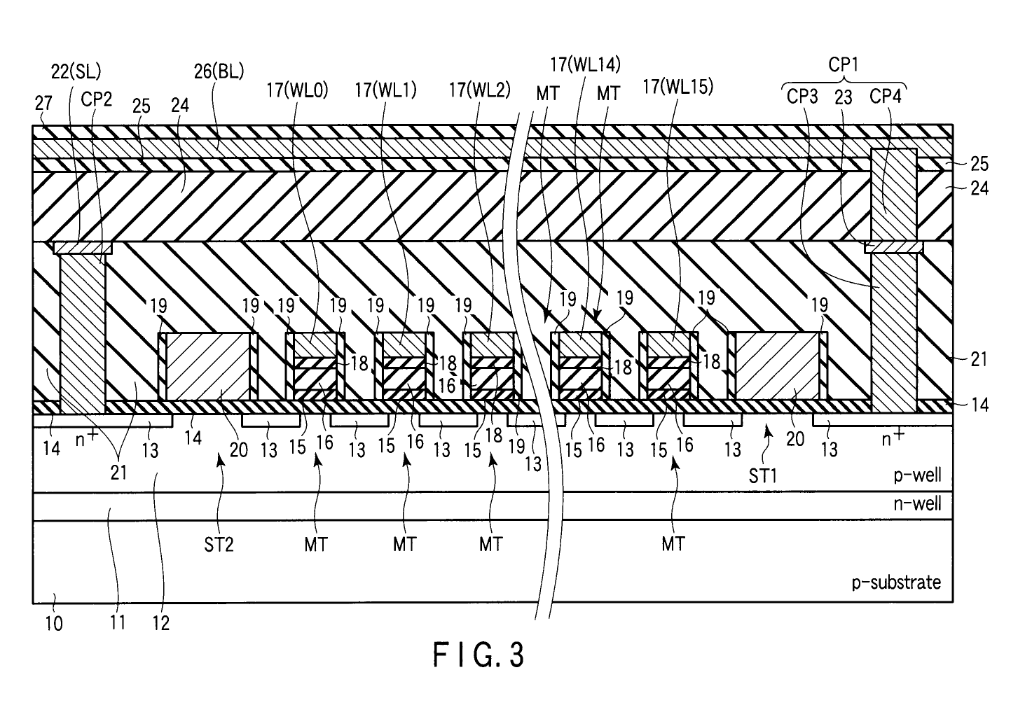

Now, the sectional configuration of the memory cell array 1 will be described with reference to FIG. 3. FIG. 3 is a sectional view of the NAND cell 5 taken along line III-III in FIG. 2.

As shown in FIG. 3, an n-type well region 11 is formed in a surface region of the p-type semiconductor substrate 10. A p-type well region 12 is formed in a surface region of the n-type well region 11. A gate insulating film 14 is formed on the p-type well region 12. Stacked gates of the memory cell transistors MT and select transistors ST1 and ST2 are formed on the gate insulating film 14. The stacked gate of the gate insulating film 14 has a MONOS structure. The insulating film 15, insulating films 16 and 18, and a polycrystalline silicon layer (control gate electrode) 17 are sequentially formed on the gate insulating film 14. The insulating film 16 is formed of a material with a higher dielectric constant than, for example, a material for the insulating film 14. The gate electrode of each of select transistors ST1 and ST2 includes a polycrystalline silicon layer 20 on the gate insulating film 14. The surface of the polycrystalline silicon layer 20 is silicidized. The polycrystalline silicon layer 20 is hereinafter sometimes referred to as the gate electrode 20.

Here, the applicable gate insulating film 14 may be a three-layer film of SiO₂, SiN, and SiO₂, a three-layer film of SiO₂, Al₂O₃, and SiO₂, a two-layer film of SiON and SiO₂, or a three-layer film of SiO₂, Si of thickness at most 2 nm, and SiO₂.

The applicable insulating film 15 is SiN or a stacked film of SiN and one of HfAlO, HfON, HfSiN, and Al₂O₃. An insulating film 19 is formed on sidewalls of the stacked gate of the memory cell transistor MT.

The insulating film 19 is formed on the sidewalls of each of the insulating films 15, 16, and 18 and the polycrystalline silicon layer 17. The insulating film 19 has only to cover at least the entire sidewalls of the insulating film 16, and does not necessarily cover the sidewalls of the insulating film 15 and the polycrystalline silicon layer 17. The insulating film 19 may be formed on the sidewalls of the gate electrode 20 of each of select transistors ST1 and ST2.

The insulating films 18 and 19 are made up of the same material. Each of the insulating films 18 and 19 is, for example, an Al₂O₃ film formed using an atomic layer deposition (ALD) method. The insulating film 16 is, for example, an LaAlO film formed using an off-axis sputtering method. A method for manufacturing an LaAlO film using the off-axis sputtering method will be described below.

In the above-described memory cell transistor MT, the insulating film 15 functions as a charge accumulation layer in which charges are accumulated. The insulating film 16 functions as a block layer that allows charges to be trapped in the insulating film 15. The polycrystalline silicon layer 17 functions as a control gate electrode. The insulating film 18 functions as a barrier layer that prevents silicon atoms making up the polycrystalline silicon layer 17 from diffusing to the insulating film 16 during annealing. The polycrystalline layers 17 located adjacent to each other in the second direction in FIG. 2 are connected together and function as the word lines WL. The insulating films 15, 16, 18, and 19 and the polycrystalline silicon layer 17 are hereinafter sometimes referred to as the charge accumulation layer 15, the block layer 16, the barrier layer 18, the sidewall 19, and the control gate electrode 17. Also in select transistors ST1 and ST2, the polycrystalline silicon layers 20 located adjacent to each other in the second direction are connected together. The gate electrode 20 functions one of select gate lines SGS and SGD. The control gate electrode 17 may be a silicide layer containing a high-melting-point metal such as Ni, Co, W, Al, or TaN, or may have a polycide structure of polysilicon and the silicide layer.

An n+ impurity diffusion layer 13 is formed in the well region 12 surface positioned between the control gate electrode 17 and the gate electrode 20. The impurity diffusion layer 13 is shared by the adjacent transistors, and functions as a source or drain region. The region between the source and drain regions located adjacent to each other functions as a channel region. The control gate electrode 17 and the gate electrode 20, the n+ impurity diffusion layers 13, and the channel regions form MOS transistors corresponding to the memory cell transistors MT and select transistors ST1 and ST2.

An interlayer insulating film 21 is formed on the p-type semiconductor substrate 10 so as to cover the memory cell transistors MT and select transistors ST1 and ST2. Contact plug CP2 is formed in the interlayer insulating film 21 so as to reach the source-side impurity diffusion layer (source region) 13 for select transistor ST2. A metal interconnect layer 22 connected to contact plug CP2 is formed on the surface of the interlayer insulating film 21. The metal interconnect layer 22 functions as a part of the source line SL. Furthermore, a contact plug CP3 is formed in the interlayer insulating film 21 so as to reach the drain-side impurity diffusion layer (drain region) 13 for select transistor ST1. A metal interconnect layer 23 connected to contact plug CP3 is formed on the surface of the interlayer insulating film 21.

An interlayer insulating film 24 is formed on the interlayer insulating film 21. An interlayer insulating film 25 is formed on the interlayer insulating film 24. A metal interconnect layer 26 is formed on the interlayer insulating film 25. The metal interconnect layer 26 functions as the bit line BL. A contact plug CP4 is formed through the interlayer insulating films 24 and 25; contact plug CP4 has a top surface contacting the metal interconnect layer 26 and a bottom surface contacting the metal interconnect layer 23. Contact plug CP3, the metal interconnect layer 23, and contact plug CP4 function as contact plug CP1 in FIG. 2. An insulating film 27 is formed on the metal interconnect layer 26.

### <Method for Manufacturing the Memory Cell Array 1>

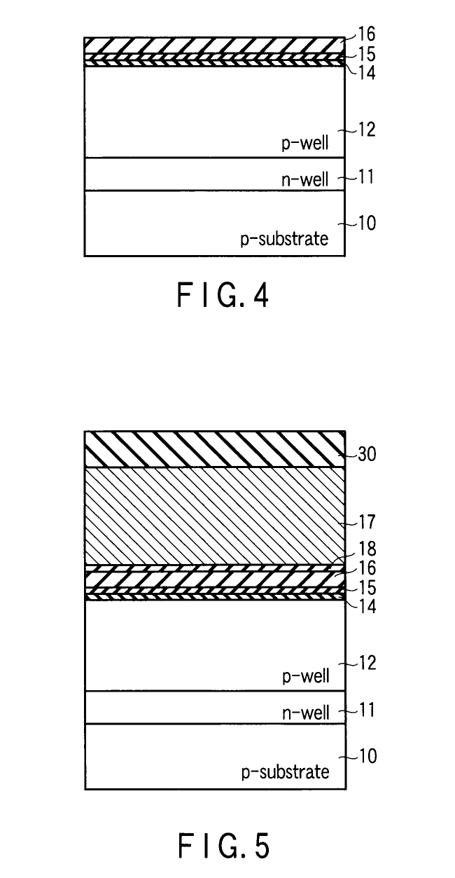

Now, a method for manufacturing the memory cell array 1 will be described with reference to FIG. 4 to FIG. 9. FIG. 4 to FIG. 9 are sectional views sequentially showing the steps of manufacturing the memory cell array 1 according to the present embodiment.

First, as shown in FIG. 4, a sacrifice oxide film (not shown in the drawings) is formed on the surface of a region on the p-type semiconductor substrate 10 in which the memory cell array 1 is to be formed. The sacrifice oxide film protects the top surface of the semiconductor substrate 10 during ion implantation. Thereafter, an n-type well region 11 is formed in the surface of the semiconductor substrate 10. A p-type well region 12 is further formed in the surface of the n-type well region 11.

Then, the sacrifice oxide film is peeled off. For example, SiO₂ is used as a material to form a gate insulating film 14 on the surface of the semiconductor substrate 10. Insulating films 15 and 16 are thereafter sequentially formed on the gate insulating film 14. The insulating film 15 is formed using SiN as a material. The insulating film 16 is formed by deposition using the off-axis sputtering method. The off-axis sputtering method will be described below. The insulating film 16 may be formed using, for example, one of crystallized LaAlO, Al-rich amorphous LaAlO, and amorphous LaAlO. In particular, the crystallized LaAlO, which has the highest dielectric constant, is more preferably used as the insulating film 16.

As shown in FIG. 5, a barrier layer 18 is formed on the insulating film 16 by, for example, the ALD method. Thereafter, a polycrystalline silicon layer 17 and an insulating film 30 as a mask material are sequentially formed.

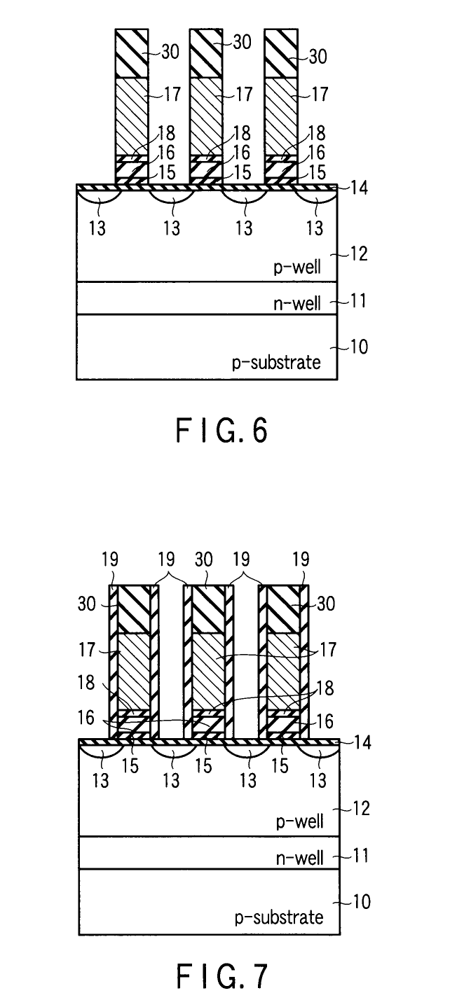

The insulating film 30, the polycrystalline silicon layer 17, and the insulating films 15, 16, and 18 are etched by a photolithography step and a dry etching step. As shown in FIG. 6, a gate electrode pattern is formed. That is, a stacked gate is completed on the semiconductor substrate 10; the stacked gate includes the charge accumulation layer formed of the insulating layer 15, the block layer formed of the insulating film 16, the barrier layer 18 formed using Al₂O₃ as a material, and the control gate electrode formed of the polycrystalline silicon layer 17. The insulating film 30 remains on the polycrystalline silicon film 17. An impurity diffusion layer 13 is formed by an ion implantation step the insulating film 30 as a mask. An impurity diffusion layer 13 function as a source region and a drain region is thus formed. An implantation amount, an ion species, and an acceleration voltage which are all appropriate to the memory cell transistors MT are adjusted by the ion implantation step.

An insulating film 19 is formed on the top surface and sidewalls of the stacked gate including the insulating film 30 by The ALD method. As shown in FIG. 7, the insulating film 19 is left only on sidewall portions of the stacked gate to obtain the sidewalls 19 by an anisotropic etching, for example, a reactive ion etching method. The barrier film 18 and the sidewalls 19 are formed of the same material. That is, the sidewalls 19 are also formed using Al₂O₃ as a material.

If the crystallized LaAlO is used as the insulating film 16, the sidewalls 19 have only to have a thickness of at least 2 nm. With the amorphous LaAlO, the film thickness of the sidewalls 19 depends on whether or not the amorphous LaAlO is Al rich. If the composition ratios of X and Y in LaxAlyOz are such that for Y=1, X≧1 (X/Y≧1), a thickness of the sidewalls 19 require at least 4 nm. On the other hand, if for Y=1, X<1 (Y/X>1) (LaxAlyOz with this composition is specifically called Al-rich amorphous LaAlO), a thickness of the sidewalls 19 at least is 2 nm.

If the amorphous LaAlO is used as the insulating film 16, when the semiconductor substrate 10 is annealed, La atoms contained in the insulating film 16 are likely to mix with Al atoms in Al₂O₃ contained in the sidewalls 19. If La and Al contained in the amorphous LaAlO have the same composition ratio or Al has a lower composition ratio than La, Al in Al₂O₃ contained in the sidewalls 19 diffuses to the insulating film 16. Thus, by using, as the insulating film 16, the amorphous LaAlO in which Al has a higher composition ratio than La or the crystallized LaAlO, Al₂O₃ The sidewalls 19 can be function as blocking insulator even if a film thickness of the sidewalls 19 is 2 nm.

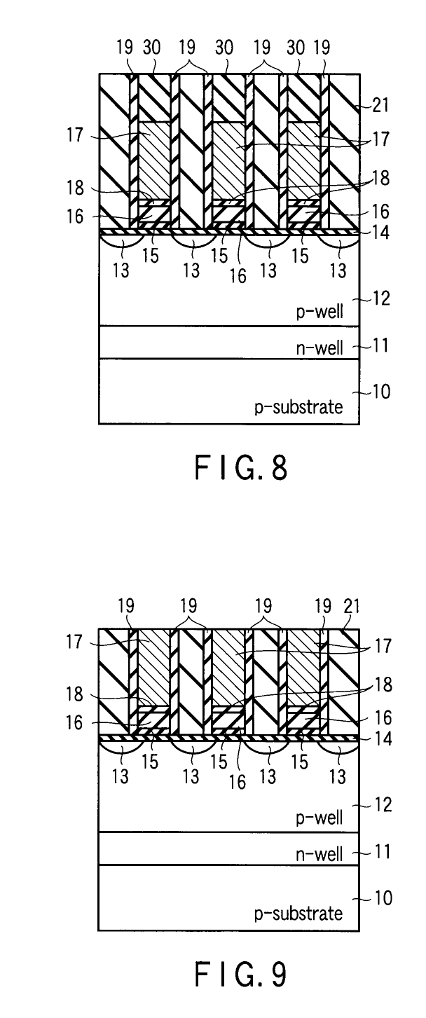

As shown in FIG. 8, an interlayer insulating film 21 is formed between the stacked gates using, for example, SiO₂ as a material. The semiconductor substrate 10 is thereafter annealed at about 1,000° C. to immobilize the impurity of the impurity diffusion layer 13.

As shown in FIG. 9, the interlayer insulating film 21 and the insulating films 19 and 30 are removed by a chemical mechanical polishing (CMP) method using the control gate electrode 17 as a stopper. The memory cell transistors MT in FIG. 9 are obtained through the above-described steps.

Although not shown in the drawings, the gate electrodes 20 and sidewalls 19 of select transistors ST1 and ST1 are formed simultaneously with (or around the time of) the formation of the stacked gates of the memory cell transistors MT.

Then, on the p-type semiconductor substrate 10, interlayer insulating films 21, 24, and 25 are formed over the memory cell transistors MT. Contact plugs CP1 and CP2 are further formed which exhibit the characteristics of high-melting-point metal, for example, tungsten or molybdenum. Metal interconnect layers 22 and 26 are also formed using, for example, aluminum. Thus, a NAND cell 5 configured as shown in FIG. 3 can be obtained.

### <Method for Depositing the Block Layer 16>

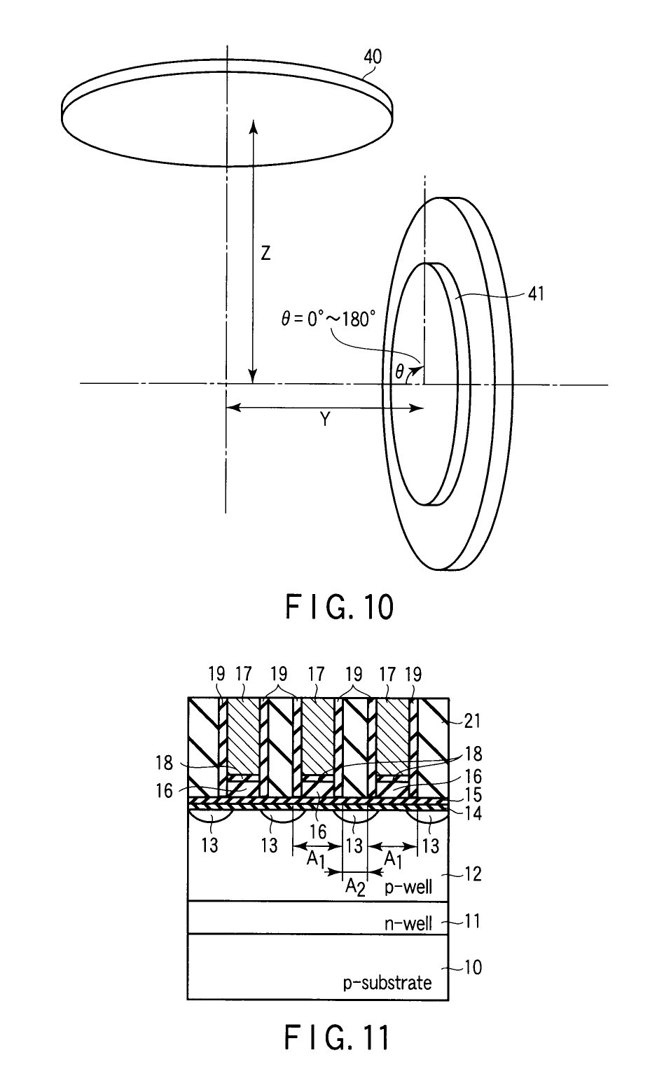

Now, a method for depositing the block layer 16 using LaAlO as a material will be described with reference to FIG. 10. FIG. 10 shows a sputtering apparatus that deposits the block layer 16. That is, the block layer 16 is deposited mainly using the sputtering method. The sputtering method will be described below.

The sputtering method is classified into an on-axis sputtering method and the off-axis sputtering method according to the positional relationship between a substrate and a target. In the on-axis sputtering method, the sputter target is located at an angle at which the target can face the substrate. On the other hand, for a sputtering apparatus adopting the off-axis sputtering method shown in FIG. 10, a target 41 is installed at an angle at which the target 41 is prevented from facing a substrate 40, that is, the target 41 is installed perpendicularly to a surface of the substrate 40. For example, the target 41 has an operating range corresponding to an angle of 90°≦θ<180° to the normal to the surface of the substrate 40. When the angle θ between the normal to the target 41 and the normal to the substrate 40 is 90°, this method is called off-axis sputtering. Thus, with the off-axis sputtering method, highly accelerated ions and neutral atoms (particles) from the target 41 can be prevented from entering films on the surface of the substrate 40. In the sputtering apparatus shown in FIG. 10, if the target 41 lies opposite the substrate 40, that is, the angle θ of the target is 180°, the apparatus is used for the on-axis sputtering method. However, the off-axis sputtering method is not limited to the angle θ=90° but only requires that the substrate 40 and the target 41 do not lie opposite each other (that is, 0°<θ<180°). More preferably, the angle θ=90°.

The on-axis sputtering method and the off-axis sputtering method are also characterized as follows. With the on-axis sputtering method, during deposition, highly accelerated particles or ions almost perpendicularly enter the films on the surface of the substrate. Thus, the deposition of the films before the bonding on the surface progresses sufficiently. In contrast, the off-axis sputtering method prevents the particles or ions from entering the films on the surface of the substrate.

Now, a method of using the off-axis sputtering method to deposit particularly a crystallized LaAlO film forming the block layer 16 will be described with reference to FIG. 10. As shown in FIG. 10, the substrate 40 and the target 41 are arranged such that the normals to the substrate 40 and the target 41 cross at right angles. That is, the angle θ of the target 41 to the substrate 40 is 90°. In the illustrated off-axis sputtering method, the target 41 is, for example, LaxAlyOz (each of x, y, and z denotes a composition ratio), that is, the target 41 is supplied with La, Al, and O. Namely, the crystallized LaAlO film may be deposited by sputtering in an At atmosphere at about 600° C. using LaxAlyOz as the target 41.

In the present example, the La, Al, and O ions diffuse to the surface of the substrate 40 and bond to the films on the surface. Thus, a crystallized LaAlO film in which the composition ratio of La to Al is 1:1 is formed. Alternatively, an Al-rich amorphous LaAlO film or an amorphous LaAlO film can be formed by changing the composition ratio of LaAlO and the temperature in the Ar atmosphere

With reference to FIG. 10, the off-axis sputtering method has been described taking the use of the single target 41 as an example. However, another target may be provided. That is, sputtering may be performed with another target positioned so as to lie orthogonally to the normal to the substrate 40 and opposite the target 41.

### Effects of the Present Embodiment

As described above, the NAND flash memory and the method for manufacturing the NAND flash memory according to the present embodiment enable operational reliability to be improved. This effect will be described below in detail with reference to a comparative NAND flash memory (comparative example).

As a comparative example, for example, a memory cell transistor MT in which Al₂O₃ is used as the block layer 16 in the stacked gate will be described. As described above, it is suitable to form the block layer 16 with a short electrical distance and a long physical distance. However, the dielectric constant of Al₂O₃ may hinder the block layer 16 from functioning adequately. That is, a voltage applied to the control gate electrode 17 in the stacked gate may fail to be transmitted to the gate insulating film 14. This may disadvantageously prevent the memory cell transistor MT from exhibiting a sufficient on/off ratio. Here, the on/off ratio is, for example, the ratio of the minimum value (hereinafter referred to as Imin) of a current flowing through the memory cell transistor MT when a voltage is applied to the control gate electrode 17 of the memory cell transistor MT to make the bit line BL and source line SL connected to the memory cell transistor MT electrically continuous, to the maximum value (hereinafter referred to as Imax) of a current flowing even in an electrically discontinuous state. That is, a decrease in on/off ratio (Imin/Imax) degrades cell characteristics. Moreover, an electric field applied to the gate insulating film 14 is weaker toward each end of the gate insulating film 14 with respect to a central part of the gate insulating film 14. That is, the electric field from the control gate electrode 17 to the gate insulating film 14 diffuses. A possible material for the block layer 16 other than Al₂O₃ is LaAlO. However, no appropriate method for depositing LaAlO has been established.

Thus, the present embodiment enables LaAlO to be deposited using the off-axis sputtering method.

However, simply depositing an LaAlO film as the block layer 16 may pose the following problem. LaAlO originally has the property of mixing readily with SiO₂ under annealing. Thus, the use of LaAlO as the block layer 16 is valuable but may pose a problem in terms of the reliability of the memory cell transistor MT. That is, in the step shown in FIG. 9, when annealing is performed without the insulating film 19 functioning as the sidewalls of the stacked gate and the insulating film 18 formed between the insulating film 16 and the control gate electrode 17, the following problem may occur.

During annealing, when the LaAlO film comes into contact with a material containing Si, for example, atoms in the polycrystalline silicon layer 17 and the interlayer insulating film 21 diffuse to the block layer 16. Then, the dielectric constant of the block layer 16, composed of LaAlO, decreases because an equivalent oxide thickness (EOT) is increase. Here, the equivalent oxide thickness EOT refers to the film thickness of any of various materials in terms of a silicon oxide film. That is, a material with a higher dielectric constant than the silicon oxide film enables a reduction in equivalent oxide thickness EOT. However, when the atoms in the polycrystalline silicon layer 17 and the interlayer insulating film 21 diffuse to the block layer 16, the substantial dielectric constant of the block layer 16 decreases because of increasing the equivalent oxide thickness EOT.

Thus, even application of a predetermined voltage to the control gate electrode 17 fails to allow an electric field generated by the control gate electrode 17 to be sufficiently applied to the gate insulating film 14. As a result, the memory cell transistor MT operates unstably when a write operation, an erase operation, or a read operation is performed on the memory cell transistor MT.

However, the NAND flash memory and the method for manufacturing the NAND flash memory according to the present embodiment allow the above-described problems to be solved and enable the operating reliability of the NAND flash memory to be improved. This will be described below in detail.

In the NAND flash memory according to the present embodiment, the structure shown in FIGS. 3 and 9 is used to prevent the LaAlO film, forming the block layer 16, from mixing with SiO₂ forming the interlayer insulating film 21 or the polycrystalline silicon layer 17 during annealing (for example, the annealing step described with reference to FIG. 8); the barrier layer 18 is formed between the block layer 16 and the polycrystalline silicon layer 17, with the sidewalls 19 formed for the stacked gate. Thus, during the annealing, the LaAlO film can be prevented from mixing with the material containing Si. Consequently, in the present embodiment, the barrier layer 18 and the sidewalls 19 can protect the block layer 16 from the polycrystalline silicon layer 17 and the interlayer insulating film 21. As a result, it is possible to increase in the equivalent oxide thickness EOT of the block layer 16 can be prevented. That is, the equivalent oxide thickness EOT of the block layer 16 can be made as thin as possible.

Of course, it is not restricted the annealing as shown in FIG. 8. The annealing step includes all the annealing steps of manufacturing process to improve property of the insulating films as a densify. After the formation of the sidewalls 19, the semiconductor substrate 10 is subjected to a plurality of annealing steps. Even during these annealing steps, the possible mixing of the LaAlO film and the material containing Si can be prevented.

Moreover, since the insulating film 19 is formed as the sidewalls of the stacked gate, the electric field applied to the gate insulating film 14 can be prevented from diffusing. That is, the electric field can be almost constant at the central part of the gate insulating film 14 and at each end of the gate insulating film 14. This results from the dielectric constant of the Al₂O₃ film used to form the insulating film 19. That is, the Al₂O₃ film has a greater dielectric constant than the members of the stacked gate (other than the insulating film 18). Thus, the electric field applied to the gate insulating film 14 is unlikely to diffuse, and concentrates on the gate insulating film 14. This provides the memory cell transistor MT with a sufficient on/off ratio, thus enabling the operating reliability to be improved.

### Second Embodiment

Now, a semiconductor memory device and a method for manufacturing the semiconductor memory device according to the second embodiment will be described. Like the above-described first embodiment, the present embodiment will be described taking a NAND flash memory of the MONOS structure as an example. The present embodiment corresponds to the first embodiment in which the insulating film 15 in FIG. 9 is connected to both of the adjacent memory cell transistors MT. The remaining part of the configuration of the second embodiment is the same as that of the first embodiment. Only differences from the first embodiment will be described below with reference to FIG. 11. The same components as those of the first embodiment are denoted by the same reference numerals and will not be described below.

As shown in FIG. 11, the region in which the control gate electrode 17 is formed is labeled A1. The region in which the control gate electrode 17 is not formed is labeled A2. Then, the insulating film 15 is formed not only on the gate insulating film 14 in region A1 but also on the gate insulating film 14 in region A2. The insulating films 15 in regions A1 and A2 are connected together. That is, in region A2, the surface of the insulating film 15 is exposed between the stacked gates. However, the insulating film 15 in region A2 does not substantially function as a charge accumulation layer. Only the insulating film 15 in region A1 functions as a charge accumulation layer.

Furthermore, in the example shown in FIG. 11, the film thickness of the insulating film 15 is almost the same in both regions A1 and A2 or slightly thinner in region A2 than in region A1. The remaining part of the configuration of the second embodiment is as described in the first embodiment, and will thus not be described in detail.

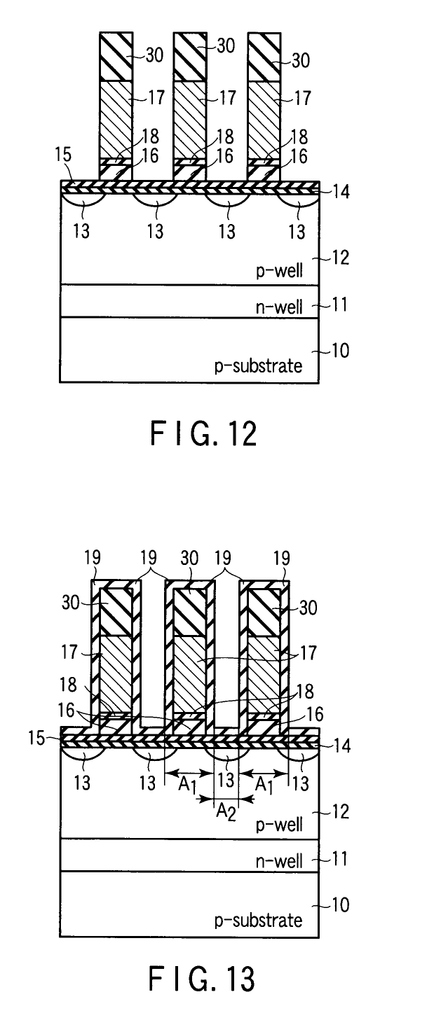

Now, a process of manufacturing a NAND flash memory according to the second embodiment will be described. The process of manufacturing the NAND flash memory according to the second embodiment corresponds to the process according to the first embodiment shown in FIG. 6. As shown in FIG. 12, after removal of the insulating film 16, dry etching is stopped.

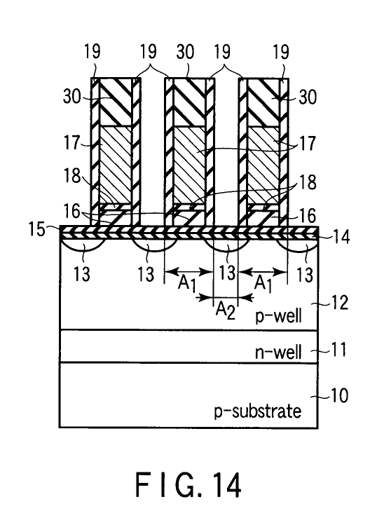

As shown in FIG. 13, the insulating film 19 is formed on an upper surface of the stacked gate and a side surface of the stacked gate by ALD method. As shown in FIG. 14, similar to steps in FIG. 7, an insulating film is formed only on the sidewalls of a stacked gate using an insulating film 15 as an etching stopper. For example, if the insulating film is formed using Al₂O₃ as a material, then even for anisotropic etching such as the RIE method, an appropriate etching selection ratio can be easily determined for SiN and an insulating film 19 formed using Al₂O₃ as a material. As a result, even if the insulating film 19 formed in region A2 is over-etched, the insulating film 15 functions as a stopper to prevent parts of the semiconductor substrate 10 located in regions A2 from being etched. Thus, what is called “gouging” can be prevented. That is, it is possible to decrease in cell current can be prevented.

Additionally, if the insulating film 19 is over-etched, the insulating film 15 of labeled A2 is slightly etched. Thus, the film thickness of the insulating film 15 may vary between regions A1 and A2. The film thickness may be larger in region A1 than in region A2. The subsequent steps are similar to those of the first embodiment and will thus not be described.

### [Modification 1]

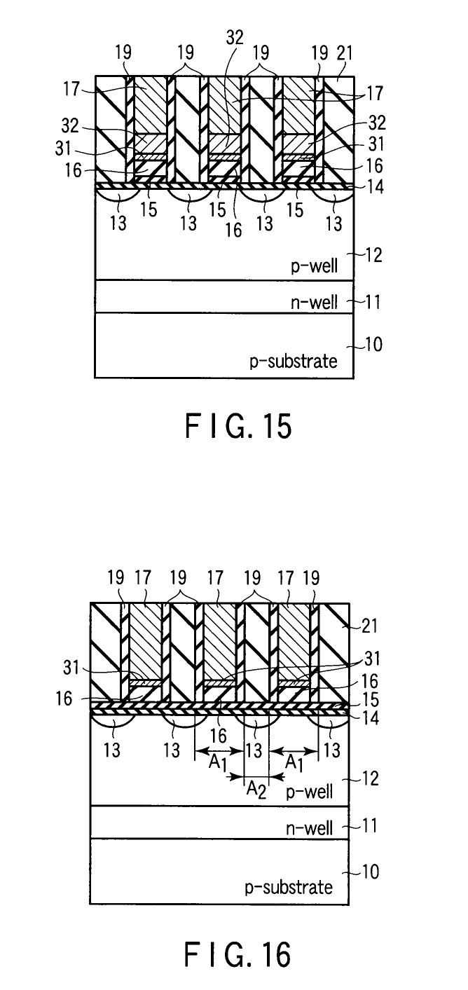

A modification of the above-described first embodiment is shown in FIG. 15. FIG. 15 is a sectional view of a NAND flash memory of the MONOS structure according to a modification of the first embodiment. Only differences from the first embodiment will be described below.

As shown in FIG. 15, the insulating film 18 shown in FIG. 9 for the first embodiment is replaced with a metal film 31. In this modification, a polycrystalline silicon layer 17 has a partial silicide structure in which the lower part is composed of a polycrystalline silicon layer 32, whereas the upper part is composed of metal silicide. The metal film 31 is formed of metal with a high work function, for example, Ta, TaN, W, WNₓ, Pt, RuO, Ti, TiNTi₃Al, Ti₂AlN, Ni, Hf, Nb, Mo, RuO₂, Ir, Co, or Cr. The remaining part of the configuration of the modification is the same as that of the first embodiment, and will thus not be described.

### <Method for Manufacturing the Memory Cell Array 1 According to Modification 1>

A process of manufacturing a NAND flash memory according to Modification 1 corresponds to the process according to the first embodiment in which in the step shown in FIG. 5, the metal film 31 is formed on the insulating film 16. That is, the metal film 31 may be formed in place of the barrier layer 18.

The NAND flash memory shown in Modification 1 of the first embodiment is applicable to the NAND flash memory shown in the above-described second embodiment. That is, in FIG. 15, the insulating film 15 may be connected to both of the adjacent memory cell transistors MT.

### [Modification 2]

A modification of the above-described second embodiment is shown in FIG. 16. FIG. 16 is a sectional view of a NAND flash memory of the MONOS structure according to a modification of the second embodiment. Only differences from the second embodiment will be described below.

As shown in FIG. 16, the insulating film 18 shown in FIG. 11 for the second embodiment is replaced with a metal film 31. The metal film 31 is formed using, for example, TaN. The surface of the polycrystalline silicon 17 is metal-silicidized. The remaining part of the configuration of the modification is the same as that of the second embodiment, and will thus not be described.

A process of manufacturing a NAND flash memory according to Modification 2 corresponds to the manufacturing process according to the second embodiment in which the metal film 31 is pre-formed on the insulating film 16 shown in FIG. 5 as is the case with the above-described manufacturing process according to Modification 1. The subsequent manufacturing steps are the same as those of the process of manufacturing the NAND flash memory according to the second embodiment and will thus not be described.

The NAND flash memory shown in Modification 2 of the second embodiment is applicable to the NAND flash memory shown in the above-described second embodiment. That is, in FIG. 16, the insulating film 15 may be connected to both of the adjacent memory cell transistors MT.

### <Effects of the Modifications>

The NAND flash memories according to Modifications 1 and 2 can exert effects similar to those of the NAND flash memories according to the above-described first or second embodiment. That is, even if the insulating film 18 is replaced with the metal film 31, the metal film 31 functions as a barrier layer. Thus, the insulating film 16, formed using LaAlO as a material, can be prevented from mixing with the polycrystalline silicon layer 17 during annealing. The successful prevention of mixing of the insulating layer 16 and the interlayer insulating film 21 is also apparent from the first embodiment. In particular, formation of the metal film 31, offering a high work function, on the top surface of the insulating film 6 increases the level of the interface between the insulating film 16 and the control gate electrode 17, that is, a barrier height. Namely, when a high voltage is applied to the semiconductor substrate 10 side, the modifications enable a reduction in possible leakage from the control gate electrode 17 to the insulating film 15, in which charges are accumulated. Therefore, the modifications allow erase characteristics to be improved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a plurality of memory cell transistors each comprising a gate electrode section including a charge accumulation layer formed on a semiconductor substrate via a gate insulating film, a first insulating film formed on the charge accumulation layer using a material with a higher dielectric constant than the gate insulating film, and a control gate formed on the first insulating film, and an impurity diffusion layer as a source or a drain;
a plurality of barrier films formed on a side surface of the gate electrode section to cover a side surface of at least the first insulating film and formed between the first insulating film and the control gate; and
a plurality of second insulating films formed on the semiconductor substrate and each formed between the gate electrode sections of adjacent ones of the plurality of memory cell transistors;
wherein during annealing of the plurality of memory cell transistors, the plurality of barrier films prevent atoms comprising the second insulating film and the control gate from diffusing to the first insulating film.

2. The semiconductor memory device according to claim 1, wherein the charge accumulation layer is an insulating film, and is one of SiN and a stacked film of SiN and one of HfAlO, HfON, HfSiN, and Al₂O₃.

3. The semiconductor memory device according to claim 1, wherein the charge accumulation layer is also formed between the gate electrode sections of the adjacent ones of the plurality of memory cell transistors.

4. The semiconductor memory device according to claim 1, wherein the first insulating film is one of crystallized LaAlO and Al-rich amorphous LaAlO, and the plurality of barrier films are Al₂O₃.

5. The semiconductor memory device according to claim 1, wherein the first insulating film is amorphous LaAlO, and the plurality of barrier films are Al₂O₃ with a thickness of at least 4 nm.

6. The semiconductor memory device according to claim 1, wherein at least one of the plurality of barrier films which is formed between the first insulating film and the control gate is a metal film.

7. A semiconductor memory device comprising:
a plurality of memory cell transistors each comprising a gate electrode section including a charge accumulation layer formed on a semiconductor substrate via a gate insulating film, a first insulating film formed on the charge accumulation layer using a material with a higher dielectric constant than the gate insulating film, and a control gate formed on the first insulating film, and an impurity diffusion layer as a source or a drain;
a first barrier film formed on a side surface of each gate electrode section to cover a side surface of at least the first insulating film;
a second barrier film formed between the first insulating film and the control gate; and
a plurality of second insulating films formed on the semiconductor substrate and each formed between the gate electrode sections of adjacent ones of the plurality of memory cell transistors;
wherein the first and second barrier films prevent diffusion of an electric field traveling from the control gate to the gate insulating film.

8. The semiconductor memory device according to claim 7, wherein the charge accumulation layer is an insulating film, and is one of SiN and a stacked film of SiN and one of HfAlO, HfON, HfSiN, and Al₂O₃.

9. The semiconductor memory device according to claim 7, wherein the charge accumulation layer is also formed between the gate electrode sections of the adjacent ones of the plurality of memory cell transistors.

10. The semiconductor memory device according to claim 7, wherein the first insulating film is one of crystallized LaAlO and Al-rich amorphous LaAlO, and the second barrier film is Al₂O₃.

11. The semiconductor memory device according to claim 7, wherein the first insulating film is formed of amorphous LaAlO, and the second barrier film is Al₂O₃ with a thickness of at least 4 nm.

12. The semiconductor memory device according to claim 7, wherein the first barrier film is one of Ta, TaN, W, WNₓ, Pt, RuO, Ti, TiNTi₃Al, Ti₂AlN, Ni, Hf, Nb, Mo, RuO₂, Ir, Co, or Cr.

13. A semiconductor memory device manufacturing method comprising:
forming a charge accumulation layer on a semiconductor substrate via a gate insulating film;
forming a first insulating film on the charge accumulation layer and a dielectric of the first insulating film is higher than that of the gate insulating film;
forming a barrier film on the first insulating film;
forming a conductive film on the barrier film;
patterning the conductive film, the barrier film, and the first insulating film to form a gate electrode section;
injecting an impurity into a surface of the semiconductor substrate to form a source and a drain, thus forming a memory cell transistor;
forming a second insulating film on a side surface of the first insulating film in the gate electrode section;
forming a third insulating film covering the memory cell transistor, on the semiconductor substrate; and
annealing the memory cell transistor after forming the second insulating film.

14. The method according to claim 13, wherein the forming a charge accumulation layer is used by off-axis sputtering.

15. The method according to claim 13, wherein the charge accumulation layer is also formed between the gate electrode sections of the adjacent ones of the plurality of memory cell transistors.

16. The method according to claim 13, wherein the first insulating film is one of crystallized LaAlO and Al-rich amorphous LaAlO, and a second insulating film is Al₂O₃.

17. The method according to claim 13, wherein the first insulating film is formed of amorphous LaAlO, and a second insulating film is formed of Al₂O₃ with a thickness of at least 4 nm.

18. The method according to claim 16, wherein the Al₂O₃ is formed using an atomic layer deposition (ALD) method.

19. The method according to claim 15 further comprising; anisotropic etching the second insulating film using the charge accumulation layer as an etching stopper after forming the second insulating film.
